(19) United States
(12) Patent Application Publication
(10) Pub. No.: US 2026/0322290 A1
(43) Pub. Date: Oct. 15, 2026

(54) INTERNET-OF-TREES BASED SELF POWERED DEFORESTATION SENSING

(71) Applicant: National University of Computer and Emerging Sciences, Islamabad (PK)

(72) Inventors: Talha Rashid, Islamabad (PK); Aqsa Ehsan, Islamabad (PK); Hassan Saif, Faisalabad (PK)

(73) Assignee: National University of Computer and Emerging Sciences, Islamabad (PK)

(21) Appl. No.: 19/175,886

(22) Filed: Apr. 10, 2025

(51) Int. Cl. H02N 1/04; H02J 7/14; H03L 7/08

(52) U.S. Cl. CPC H02N 1/04; H02J 7/14; H03L 7/08; H02J 2207/50

(57) ABSTRACT

An internet-of-trees (IoTr) based insertable nail-shaped self-powered sensing system to monitor the position of trees and transmit collected data regarding tree position via a data transmission network based on factors including but not limited to signal transmission resulting from motion enabled triboelectric power generation. Sensing system includes a triboelectric nanogenerator configured to operate in a contact-separation mode to generate electrical energy; a harvesting interface to convert an output of the triboelectric nanogenerator to a DC voltage; integrated circuit coupled to the triboelectric nanogenerator; a crystal oscillator coupled to the integrated circuit; and a data transmission system coupled to the integrated circuit, wherein the data transmission system is configured to transmit a transmission signal to one or more base stations.

### FIELD OF THE INVENTION

At least one implementation generally relates to position monitoring and tracking systems for moveable objects such as planted trees and more specifically to a triboelectric-powered internet-of-trees (IoTr) position tracking sensing system.

### BACKGROUND

Countries such as Pakistan have been proactive lately in its efforts to align national projects with globally outlined policy frameworks dealing with action against climate change. Climate change adaptation is a pressing concern for developing countries, particularly for Pakistan owing to the fragility of its ecosystems and vulnerability with regards to the consequences of climate change. The “ten billion trees” is one of the initiatives the government has focused on to demonstrate resilience in the face of this global adversary. In addition to reviving forest and wildlife resources in Pakistan, improving the overall conservation of the existing protected areas, and encouraging ecotourism, community engagement, and job creation, this venture will enable Pakistan to bank carbon credits crucial for economic growth and development through maximizing industrial endeavors. By alleviating the current burden that is posed in the form of carbon tax, redemption of carbon credits enabled via this initiative will be a key factor in restoring country’s stability. The national GHG inventory project aims at developing a framework for compiling GHG inventories, data collection, data sharing, data reporting, and institutional arrangements according to the United Nations framework convention on climate change (UNFCCC) guidelines and Paris agreement. However, the actual data pertaining to vital trees is unknown and relies simply on data collected at the time of plantation. Mismanagement, insufficient data, and lack of knowledge are simply a few of the threats that stand in the way of accurate collection of this information. As such, there is a pertinent need to develop a mechanism to ensure transparent and efficient data collection to redeem accurate carbon credits. The mechanism also addresses some of the United Nation’s sustainable development goals.

### SUMMARY

At least one implementation discloses an apparatus comprising an internet-of-trees (IoTr) based insertable nail-shaped self-powered sensing system to monitor the position of trees and transmit collected data regarding tree position via a data transmission network based on factors including but not limited to signal transmission resulting from motion enabled triboelectric power generation.

In at least one implementation, the apparatus comprises a triboelectric nanogenerator configured to operate in a contact-separation mode to generate electrical energy. In at least one example, the triboelectric nanogenerator comprises: a mechanical mass coated with a first triboelectric material on a bottom surface of the mechanical mass; a second triboelectric material placed adjacent to the mechanical mass, wherein the second triboelectric material is of an opposite polarity than the first triboelectric material; and a mechanical spring configured to aid the contact-separation mode of the first triboelectric material and the second triboelectric material. In at least one implementation, the apparatus comprises a harvesting interface configured to convert an output of the triboelectric nanogenerator to a DC voltage, wherein the harvesting interface includes a supercapacitor to store harvested electrical energy based on the DC voltage. In at least one implementation, the apparatus comprises an integrated circuit (e.g., processing electronics) coupled to the triboelectric nanogenerator. In at least one implementation, the apparatus comprises a crystal oscillator coupled to the integrated circuit, the crystal oscillator configured to generate a reference signal for a phase locked loop. In at least one implementation, the apparatus comprises a data transmission system coupled to the integrated circuit, wherein the data transmission system is configured to transmit a transmission signal to one or more base stations.

In at least one implementation, a method of communicating a payload message of a tree is provided using a sensing system, the method comprises inserting a nail-shaped casing in a tree, wherein the nail-shaped casing houses the sensing system. The method further includes generating a triboelectric charge with a triboelectric nanogenerator in a contact-separation mode, wherein the triboelectric nanogenerator comprises a first triboelectric material coated on a mechanical mass and a second triboelectric material of opposite polarity adjacent to the mechanical mass. The method further includes storing the triboelectric charge in a supercapacitor and harvesting regulated DC voltage from the triboelectric charge that is stored. The method further includes supplying the harvested regulated DC voltage to integrated circuit and data transmission system. The method further includes modulating the payload message with the integrated circuit into a modulated signal. The method further includes transmitting the modulated signal with a mechanical spring or a patch antenna to one or more base stations, wherein the modulated signal is received at one or more base stations, and wherein the one or more base stations demodulate the modulated signal to determine a unique tree identification (ID).

### BRIEF DESCRIPTION OF THE DRAWINGS

The accompanying drawings, which are incorporated in and constitute part of this specification, illustrate embodiments of the invention, and together with the description explain the principles of the invention as examples. The examples illustrated herein are presently preferred, it being understood by those skilled in the art, however, that the invention is not limited to the precise arrangements and instrumentalities shown.

FIG. 1 illustrates an internet-of-trees (IoTr) based nail-shaped sensing system, in accordance with at least one implementation.

FIG. 2 illustrates an example implementation of sensing system of FIG. 1, in accordance with at least one implementation.

FIG. 3 illustrates a wireless transmission framework applying the implementation of FIG. 2 for a forest, in accordance with at least one implementation.

FIG. 4 illustrates example structures of sensing system of FIG. 1, based on modes of operation of the triboelectric nanogenerator, in accordance with at least one implementation.

FIG. 5 illustrates a schematic of processing and transmission electronics of sensing system of FIG. 1, in accordance with at least one implementation.

FIG. 6 illustrates a block diagram of power, control, and regulation electronics encased in electronics housing of sensing system of FIG. 1, in accordance with at least one implementation.

FIG. 7 illustrates a block diagram of a data transmission system of the sensing system of FIG. 1, in accordance with at least one implementation.

FIG. 8 illustrates a block diagram of a transmitter of the sensing system of FIG. 1, in accordance with at least one implementation.

FIG. 9 illustrates a triangulation technique to determine the precise location of the sensing system of FIG. 1, in accordance with at least one implementation.

### DETAILED DESCRIPTION

In at least one implementation, a triboelectric nanogenerator powered sensing system operates on an internet of trees (IoTr) mechanism where the system is capable of monitoring and transmitting a payload message of a tree. In at least one implementation, the IoTr mechanism comprises a structure comprising a casing (e.g., a nail-shaped rigid casing) enclosing integrated circuit, a data transmission system, and a dual functional mechanical spring working as a damper, and one or more antennas (e.g., 433 MHz helical antenna, and a 915 MHz patch antenna at the top of the casing for dual band transmission). In at least one implementation, sensors are placed inside the casing and powered through a triboelectric nanogenerator, which stores charge on a supercapacitor. Collected data from the individual sensor is transmitted in preprogrammed intervals to one or more base stations, in accordance with at least one implementation.

In at least one implementation, the IoTr mechanism can be used for monitoring several trees via wireless signal transmission network to report any losses sustained due to natural and human induced deforestation. In at least one implementation, the casing contains the triboelectric nanogenerator along with integrated circuit and a transmission network; hence it can be inserted in a tree branch. In at least one implementation, the system comprising the IoTr mechanism is powered through built-in triboelectric nanogenerator based harvesting system comprising of a mechanical mass and two triboelectric materials of opposite polarities. In at least one implementation, power generated by a triboelectric nanogenerator is stored in a supercapacitor through a power and charging control block. In at least one implementation, a voltage regulator and an energy monitor power the complete system and data is fed to a transmitter via integrated circuit. In at least one implementation, the transmitter transmits a dual band transmission signal using a patch antenna and a mechanical spring that acts as a helical antenna, wherein dual band transmission is adopted to reduce the redundancy. In at least one implementation, the casing is a nail-shaped rigid casing configured for easy and efficient power generation and data transmission along with the communication protocols for the system.

While various examples and implementations are discussed with reference to a tree, the examples and implementations are applicable to any moveable object (living or non-living) where the system can be penetrated in the moveable object. For instance, the moveable object can be an animal, faux tree, a moveable or vibrating part of a vehicle, etc.

The examples provided in this disclosure are explained in detail for a thorough understanding of the invention and the accompanying embodiments. All such figures including schematics, block diagrams, or preferred structures may not be drawn to scale. Furthermore, the schematics, block diagrams, or structures are to clarify the invention. One skilled in the art can understand that the core components are shown in the embodiments for a better illustration. Hence, any additional elements necessary in these circuits or structures for implementation are implicitly a part of this disclosure. All examples, systems, structures, schematics, circuits, and subcircuits that utilize the fundamental principles of the invention or have elements of the invention are hereby treated to be under the complete protection of the disclosed invention.

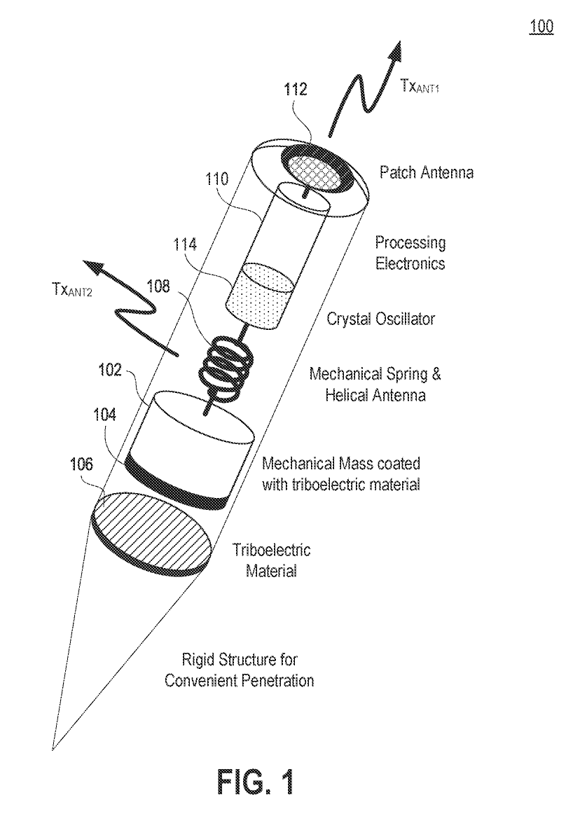

FIG. 1 illustrates a nail-shaped IoTr based sensing system 100, in accordance with at least one implementation. In at least one implementation, nail-shaped IoTr based sensing system 100 comprises a rounded head with a patch antenna 112 and a rigid structure for convenient insertion into a tree. Contact-separation mode triboelectric nanogenerator is illustrated with a mechanical mass 102 acting as an electrode and coated with triboelectric material 104 at a bottom surface. In at least one implementation, another triboelectric material 106 of opposite polarity is attached to a bottom wall of nail-shaped IoTr based sensing system 100. Energy is generated due to the back-and-forth motion of mechanical mass 102 allowing the triboelectric nanogenerator to work in contact-separation mode. In at least one implementation, mechanical spring 108 connects mechanical mass 102 with integrated circuit 110 and crystal oscillator 114. In at least one implementation, mechanical spring 108 aids the back-and-forth motion of mechanical mass 102 and acts as a helical antenna for data transmission T_{XANT2}. In at least one implementation, integrated circuit 110 is connected to crystal oscillator 114 and patch antenna 112n for data transmission T_{ANT1}. In at least one implementation, nail-shaped IoTr based sensing system 100 is approximately 2 millimeters in diameter and 20 millimeters in length, allowing it to be inserted in the freely moving branch of a tree. In at least one implementation, nail-shaped IoTr based sensing system 100 may have any other shape suitable for the application and may not be inserted rather attached with a tree at any suitable location.

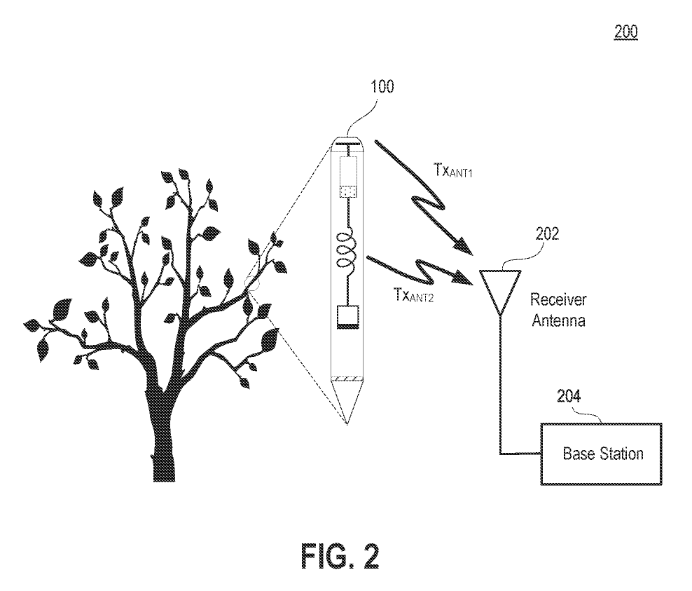

FIG. 2 illustrates implementation 200 of nail-shaped IoTr based sensing system 100 of FIG. 1, in accordance with at least one implementation. In at least one implementation, sensing system 100 is directly insertable in a branch of a tree. In at least one implementation, mechanical mass 102 is coated with triboelectric material 104 at bottom and another triboelectric material 106 of opposite polarity is attached beneath the mechanical mass 102, as shown in FIG. 1. Upon movement of the mechanical mass 102, and subsequent collision, power is generated and sent to harvesting interface and integrated circuit which in turn transmits a payload message of the tree to a receiving antenna 202 of a base station 204. In at least one implementation, base station 204 may process the payload message to extract location and other information of the tree.

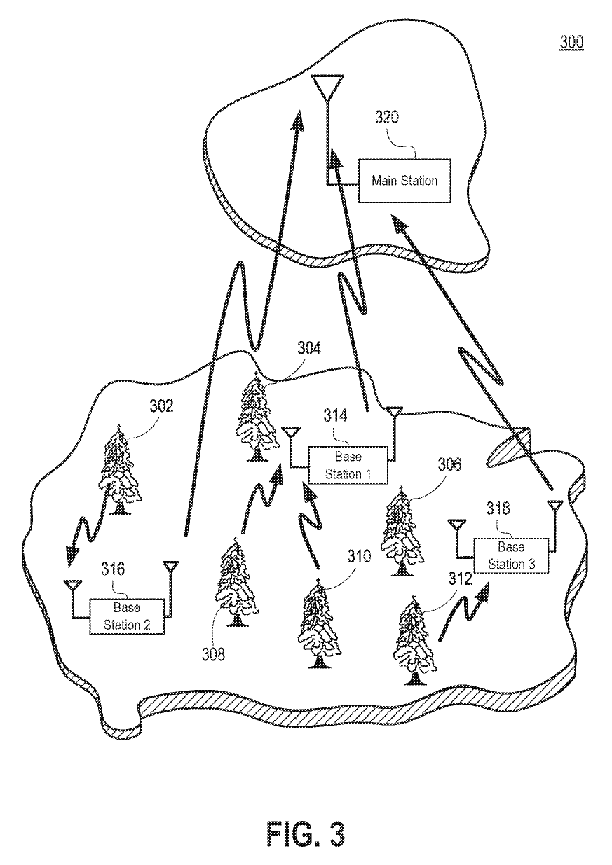

FIG. 3 illustrates a wireless transmission framework 300 using implementation 200 of FIG. 2 for a forest, in accordance with at least one implementation. In at least one implementation, sensing system 100 is mounted on stems of various trees 302, 304, 306, 308, 310, and 312 and transmits a payload message to base stations 314, 316, and 318, located within a radius of up to a finite distance (e.g., 10 kilometers) from the trees. In at least one implementation, base stations 314, 316, and 318 transmit the payload message to a main station 320 located up to, for example, 50 kilometers from base stations 314, 316, and 318. In at least one implementation, main station 320 decodes and stores the payload message for further processing.

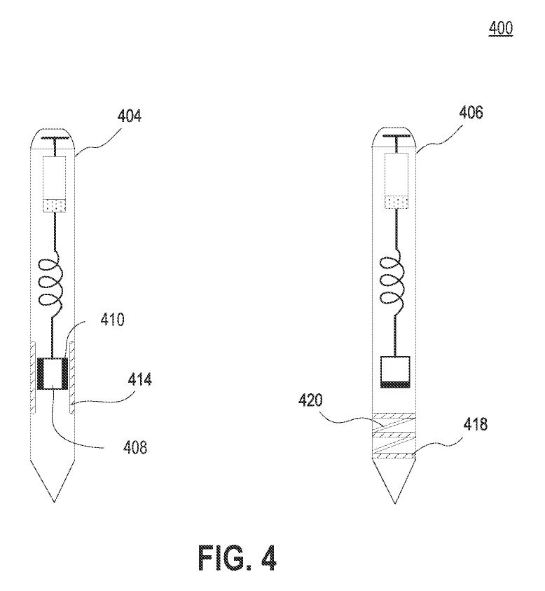

FIG. 4 illustrates a set 400 of structures 404 and 406 of sensing system 100 of FIG. 1, based on modes of operation of the triboelectric nanogenerator, in accordance with at least one implementation. In at least one implementation, structure 404 is a sliding mode triboelectric nanogenerator which generates power via sides of a mechanical mass 408 rubbing against a material 414 mounted on the walls of structure 404. Sides of mechanical mass 408 are coated with a triboelectric material 410 while material 414 is a coating of a triboelectric material with a different polarity than triboelectric material 410. Structure 406 is a contact-separation mode triboelectric nanogenerator with multiple layers that form a collapsible multi-tiered structure 418, with each fold comprising a stacking of opposite polarity materials 420 that are used to increase the voltage and subsequently the power of system, in accordance with at least one implementation. In at least one example, nail-shaped IoTr based sensing system 100 of FIG. 1 and structures 404 and 406 of FIG. 4 involve the same integrated circuit for converting energy harvested from triboelectric nanogenerator to regulated DC voltage to power transmitting electronics.

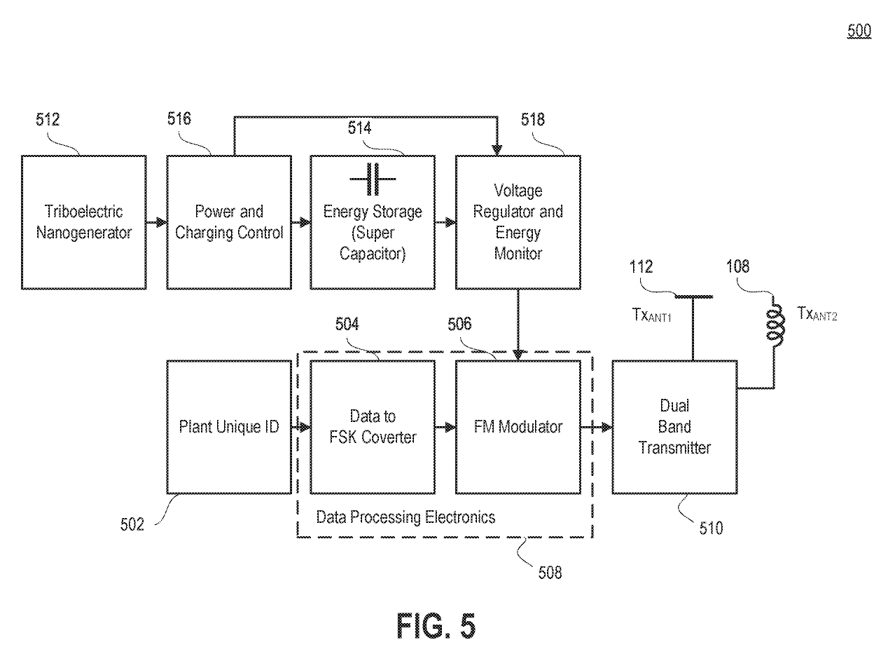

FIG. 5 illustrates a block diagram 500 of integrated circuit 110 and transmitter of nail-shaped IoTr based sensing system 100 of FIG. 1, in accordance with at least one implementation. Block diagram 500 specifies that tree’s unique ID 502 and other information is passed to a converter (e.g., frequency shift keying (FSK) converter 504) and then to a modulator 506 (e.g., FM modulator) in integrated circuit 508. In at least one implementation, integrated circuit 508 converts the information into an analog signal that can be transmitted. In at least one implementation, the modulated signal is passed on to a dual band transmitter 510 from where it is transmitted using mechanical spring 108 (e.g., and helical antenna) and patch antenna 112. In at least one implementation, mechanical spring 108 is surrounded by the water-based xylem and phloem tissues of a tree and faces significant attenuation and has a low transmission range. In at least one example, to improve the transmission range, low frequency 433MHz ISM band is utilized since it suffers less attenuation compared to the higher frequency bands, in accordance with at least one implementation. In at least one implementation, patch antenna 112 is exposed. In at least one example, patch antenna 112 utilizes a higher band of 915 MHz for a longer range. In at least one implementation, integrated circuit 508 is powered through energy generated from triboelectric nanogenerator 512 stored on a supercapacitor 514 after it has been rectified and regulated through power and charging control circuitry 516 and voltage regulator and energy monitor 518, respectively. In at least one implementation, processing and transmission electronics are powered when energy monitor 518 detects a higher energy storage in supercapacitor 514 than a threshold limit or a specific time has passed. In at least one implementation, when the energy threshold is achieved in supercapacitor 514, dual band transmitter 510 transmits a payload message repeatedly instead of a single burst.

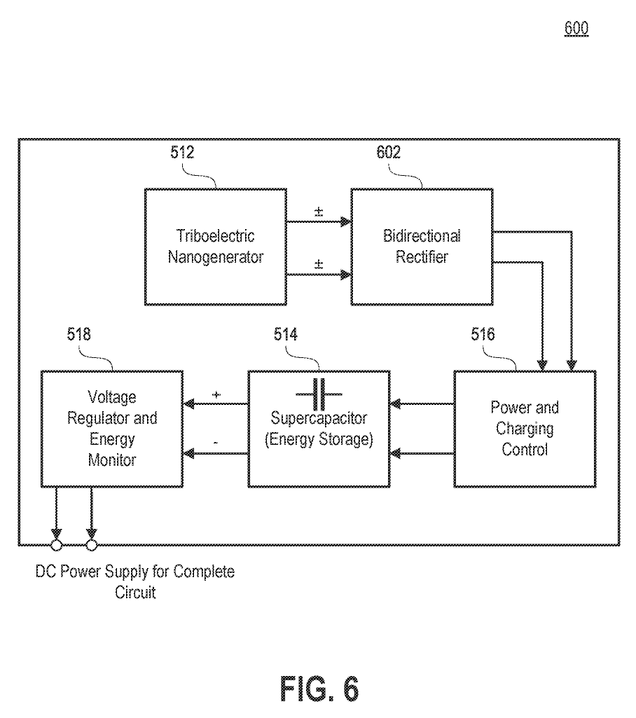

FIG. 6 illustrates a block diagram 600 of power, control, and regulation electronics encased in an electronics housing of sensing system 100 of FIG. 1, in accordance with at least one implementation. Block diagram 600 describes how the output of triboelectric nanogenerator 512 is rectified using power and charging control circuitry 516 after being rectified by a bi-directional rectifier 602. In at least one implementation, rectified voltage is stored on a supercapacitor 514 because it can provide sharp bursts of energy and operate successfully under a range of temperatures that suit the application. In at least one implementation, supercapacitor 514 is also capable of sustaining many charge-discharge cycles. Supercapacitor 514 is used to power the voltage regulator and energy monitor 518 that generates a regulated DC voltage.

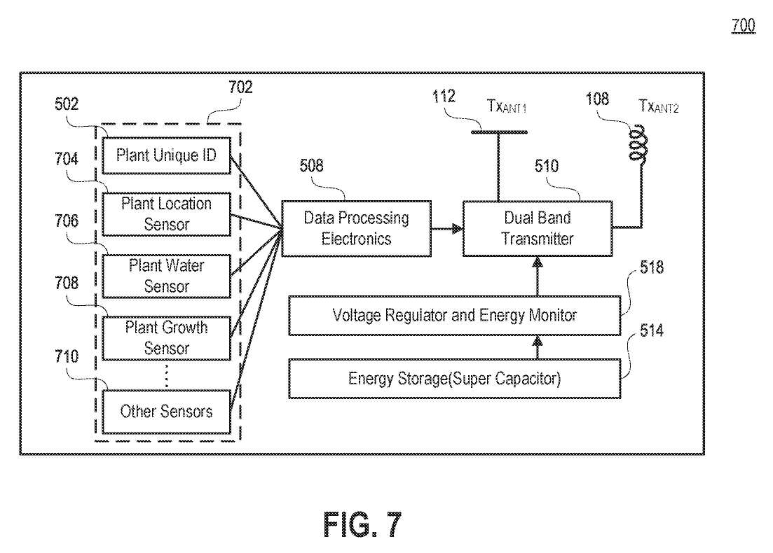

FIG. 7 illustrates a block diagram of a data transmission system 700 of sensing system 100 of FIG. 1, in accordance with at least one implementation. In at least one implementation, data is provided by various sensors of a sensor array 702 to integrated circuit 508. In at least one implementation, sensor array 702 includes a tree location sensor 704, a tree water sensor 706, a tree growth sensor 708, and/or other sensors 710 along with the tree’s unique ID 502. In at least one implementation, data is processed by integrated circuit 508 and passed on to dual band transmitter 510 where it is transmitted to the base stations using mechanical spring 108 (e.g., helical antenna) and patch antenna 112. In at least one implementation, transmitter 510 is a dual band transmitter which is powered using the energy harvested through the triboelectric nanogenerator, stored in supercapacitor 514, and regulated using the voltage regulator and energy monitor 518. In at least one implementation, transmitter 510 is powered when supercapacitor 514 voltage exceeds the threshold voltage, or if there is an adequate charge then when the prescribed time is passed. This method is effective for energy conservation and prolonging the system’s lifetime. In at least one implementation, tree location sensor is a global positioning system (GPS) like receiver, an inertial navigation system (INS) based on a 3D MEMS gyroscope, or some other suitable futuristic technology that aids the geolocation of the tree.

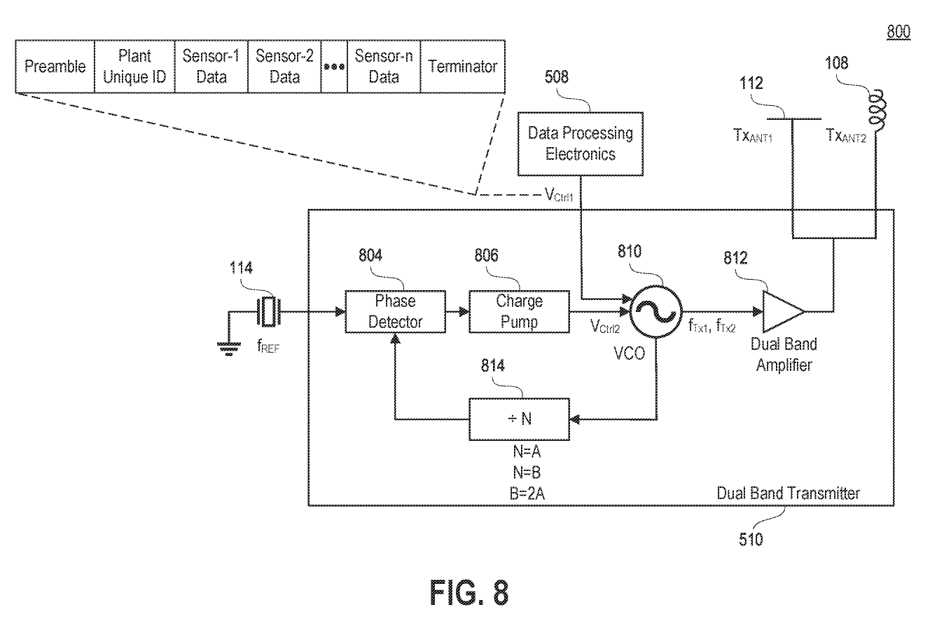

FIG. 8 illustrates a block diagram 800 of the dual band transmitter 510 of FIG. 5, in accordance with at least one implementation. Binary data containing payload message of a tree is encoded in the form of a control voltage V_{Ctrl1} by modulator 506 of integrated circuit 508. Another control voltage signal V_{Ctrl2} is generated from a phased locked loop (PLL) comprising a phase detector 804, a charge pump 806, a frequency divider 814, and a dual control voltage-controlled oscillator (VCO) 810. Crystal oscillator 114 generates reference frequency f_{REF} for the PLL which is fed to phase detector 804. Phase detector 804 compares f_{REF} with the frequency of VCO 810 and generates the error signal which is sent to charge pump 806. In at least one implementation, charge pump 806 automatically adjusts the phase of this signal according to the reference signal f_{REF}. In at least one implementation, frequency divider 814 used in PLL feedback loop has the dividing factor N of 2 and helps generating two required reference frequencies A and B of frequency divider 814. In at least one implementation, signal from charge pump 806 is fed to VCO 810, which generates modulated signals with frequencies f_{Tx1} and f_{Tx2}. This data is amplified by a dual band amplifier 812 and transmitted using the mechanical spring 108 and patch antenna 112.

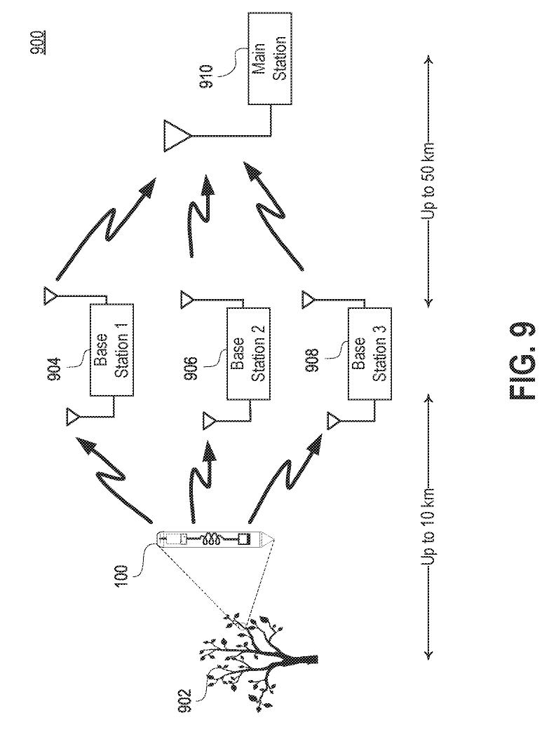

FIG. 9 illustrates a triangulation technique 900 used to determine a precise location of nail-shaped IoTr based sensing system 100 of FIG. 1, in accordance with at least one implementation. In at least one implementation, nail-shaped IoTr based sensing system 100 is inserted into a tree 902, and nail-shaped IoTr based sensing system 100 is synchronized. Three or more base stations 904, 906, and 908 receive data from nail-shaped IoTr based sensing system 100. The received data is transmitted by an individual base station e.g., 904, 906, or 908, to a main station 910 which calculates the location of sensing system 100 using a triangulation technique by measuring time a signal from nail-shaped IoTr based sensing system 100 takes to arrive. Technique 900 is used to accurately judge the location of the nail-shaped IoTr based sensing system 100 and hence, the location of tree 902, where nail-shaped IoTr based sensing system 100 is inserted. In at least one implementation, the technique of received signal strength may also be used to estimate a tree’s distance from a base station and hence, its location. In at least one implementation, other techniques for determination of tree location may be used.

In at least one implementation, a sensing system is powered through a triboelectric nanogenerator that works on the triboelectric effect; a direct consequence of contact and separation between two surfaces of triboelectric properties with opposite polarities. The surfaces in contact generate electrical charges which may be stored or connected to external circuitry to drive low-power electronics. Moreover, a metal electrode is to transfer the generated power to integrated circuit. In at least one implementation, nylon and polytetrafluoroethylene (PTFE) are utilized as triboelectric materials but any suitable material from the triboelectric series may be used to enhance the performance. In at least one implementation, the metal electrode used in the system may also be fabricated by any metal depending upon its electrical characteristics and mechanical strength.

In at least one implementation, highly elastic and light-weight mechanical spring acting as a helical antenna is used to favor the frequent back and forth movement resulting in more collisions and enhancing the overall performance of the triboelectric nanogenerator. In at least one implementation, triboelectric nanogenerator is lightweight, cost-effective, and area-efficient and therefore is easily integrated in a nail-shaped casing of the sensing system. Moreover, its nail-shaped structure allows it to be easily inserted in the branch of the tree making it convenient to be used in commercial applications. Other structures, shapes, or materials suitable for the application may also be used. In at least one implementation, any lightweight, low-power wireless transmitter may be used to communicate the payload message or the tree’s location, and the wireless transmitters used in this disclosure are not taken to be limiting.

In at least one implementation, a tree being intentionally damaged may result in the sensing system to halt, allowing identification of the harm to the tree. In at least one implementation, transportation of a felled tree may generate a charge surge crossing a threshold leading to detection by the base stations and detection of movement by the main station.

In at least one implementation, any other mode of triboelectric generators may also be employed based on convenience, performance, and ease of fabrication. Similarly, other modes, such as lateral sliding mode, free-standing mode, and single electrode mode, may also be used according to the requirements of the application.

In at least one implementation, hybrid triboelectric generators may be used to boost the system’s power. As another example, blue energy can also be used due to abundant availability and capability to generate enhanced power output.

Here, "signal" may generally refer to at least one current signal, voltage signal, magnetic signal, or data/clock signal. Here, meaning of "a," "an," and "the" include plural references. Here, meaning of "in" includes "in" and "on."

Here, “adjustment signal” or “adjusted signal” may generally refer to any signal used to adjust any other signal and more particularly to the signal generated by the integer divider after the integer divider divides the dual band transmission signal by an integer.

Here, terms “approximately,” and “near,” generally refer to being within +/- 10% of a target value. In at least one embodiment, such variation is typically no more than +/-10% of a predetermined target value.

Unless otherwise specified use of ordinal adjectives “first,” “second,” and “third,” etc., to describe a common object, merely indicate that different instances of like objects are being referred to and are not intended to imply that objects so described must be in a given sequence, either temporally, spatially, in ranking or in any other manner.

Here, “top,” “bottom,” “over,” “under,” and like in description and in claims, if any, are used for descriptive purposes and not necessarily for describing permanent relative positions. In at least one embodiment, “top,” “bottom,” “over,” “under,” and “on” as used herein refer to a relative position of one component, structure, or material with respect to other referenced components, structures or materials within a device, where such physical relationships are noteworthy. In at least one embodiment, these terms are employed herein for descriptive purposes and predominantly within context of a device z-axis and therefore may be relative to an orientation of a device. In at least one embodiment, a first material “over” a second material in context of a figure provided herein may also be “under” a second material if device is oriented upside-down relative to context of figure provided. In context of materials, one material disposed over or under another may be directly in contact or may have one or more intervening materials. Moreover, one material disposed between two materials may be directly in contact with two layers or may have one or more intervening layers. In at least one embodiment, a first material “on” a second material is in direct contact with that second material. Similar distinctions are to be made in context of component assemblies.

Here, “between” may be employed in context of z-axis, x-axis, or y-axis of a device. In at least one embodiment, a material that is between two other materials may be in contact with one or both of those materials or may be separated from both of other two materials by one or more intervening materials. In at least one embodiment, a material “between” two other materials may therefore be in contact with either of other two materials or may be coupled to other two materials through an intervening material. In at least one embodiment, a device that is between two other devices may be directly connected to one or both of those devices or may be separated from both of other two devices by one or more intervening devices.

Here, “IoTr” may generally refer to internet of trees; an internet of things protocol used to connect sensing systems to one or more base stations. Consequently, it may also refer to any transmission protocol used to relay tree data to the one or more base stations.

Here, “triboelectric” may generally refer to all modes, including but not limited to, contact-separation, free standing, and sliding mode of contact electrification whereby materials that are brought together become electrically charged upon being brought into contact.

Here, “harvesting” may generally refer to the storage of the generated electrical charge and is not limited to any particular electrical components or mechanism.

Here, “crystal oscillator” may generally refer to any apparatus to generate the reference signal for the phase detector in the phase locked loop.

Here, “supercapacitor” may generally refer to any device used for the storage of electrical charge or energy and includes but is not limited to capacitors and batteries.

Here, “nanogenerator” may generally refer to the triboelectric nanogenerator. Consequently, it may also refer to any device used for electric energy generation through vibrational motion.

Here, “payload message” may generally refer to any message transmitted by the sensing system, containing sensor information and more particularly to a message that contains a preamble, the unique ID, information from the sensor array, and a terminator but is not limited as such.

Here, “integer divider” may generally refer to any apparatus or method to divide the dual band signal generated by the VCO into an adjusted signal passed to the phase detector.

Here, “dual band amplifier” may generally refer to any apparatus or method to amplify the dual band signal generated by the VCO.

Reference in specification to "an embodiment," "one embodiment," “in at least one embodiment,” "some embodiments," or "other embodiments" means that a particular feature, structure, or characteristic described in connection with embodiments is included in at least some embodiments, but not necessarily all embodiments. Various appearances of "an embodiment," "one embodiment," “in at least one embodiment,” or "some embodiments" are not necessarily all referring to same embodiments. If specification states a component, feature, structure, or characteristic "may," "might," or "could" be included, that particular component, feature, structure, or characteristic is not required to be included. If specification or claim refers to "a" or "an" element, that does not mean there is only one element. If specification or claims refer to "an additional" element, that does not preclude there being more than one of an additional element.

Furthermore, particular features, structures, functions, or characteristics may be combined in any suitable manner in one or more embodiments. For example, a first embodiment may be combined with a second embodiment anywhere particular features, structures, functions, or characteristics associated with two embodiments are not mutually exclusive.

While at least one embodiment has been described in conjunction with specific embodiments thereof, many alternatives, modifications and variations of such embodiments will be apparent to those of ordinary skill in the art considering description herein. At least one embodiment is intended to embrace all such alternatives, modifications, and variations as to fall within broad scope of appended claims.

In addition, well-known power/ground connections to devices and other components may or may not be shown within presented figures, for simplicity of illustration and discussion, and so as not to obscure any embodiment. Further, arrangements may be shown in block diagram form to avoid obscuring any embodiment, and in view of the fact that specifics with respect to implementation of such block diagram arrangements are dependent upon the platform within which an embodiment is to be implemented (e.g., such specifics should be well within purview of one skilled in art). Where specific details (e.g., dimensions) are set forth to describe example embodiments of disclosure, it should be apparent to one skilled in art that disclosure can be practiced with or without variation of these specific details. Description of an embodiment is thus to be regarded as illustrative instead of limiting.

In at least one embodiment, structures described herein can also be described as method(s) of forming those structures or apparatuses, and method(s) of operation of these structures or apparatuses. Following examples are provided that illustrate at least one embodiment. An example can be combined with any other example. As such, at least one example can be combined with at least another example without changing scope of an example.

Example 1 is an apparatus of a position monitoring and tracking insertable IoTr based self-powered sensing system using IoTr based integrated circuit comprised of: a nail-shaped casing, wherein the nail-shaped casing houses the sensing system; a triboelectric nanogenerator, wherein the triboelectric nanogenerator works in contact-separation mode to generate electrical energy; and wherein the triboelectric nanogenerator comprises: a mechanical mass, wherein the mechanical mass is coated with a first triboelectric material on its bottom surface; a second triboelectric material, wherein the second triboelectric material is placed near the mechanical mass, and wherein the second triboelectric material is of an opposite polarity than the first triboelectric material; and a mechanical spring, wherein the mechanical spring aids the contact-separation of the first and second triboelectric materials; a harvesting interface for converting output of the triboelectric nanogenerator to a regulated DC voltage, wherein the harvesting interface includes a supercapacitor to store the harvested electrical energy; integrated circuit; a crystal oscillator for generating a reference signal for a phase locked loop; and a data transmission system for transmitting a transmission signal to one or more base stations.

Example 2 is an apparatus according to any examples herein, in particular example 1, wherein the mechanical spring of the sensing system; is conductive, lightweight and elastic; aids the generation of triboelectricity by controlling an extent of vertical back and forth motion of the mechanical mass; and acts as an antenna and aids in transferring tree data to the one or more base stations.

Example 3 is an apparatus according to any examples herein, in particular example 1, wherein the integrated circuit is powered if the harvested electrical energy stored in the supercapacitor is more than a predefined threshold, and wherein the integrated circuit comprise: a power and charging control circuitry for controlling an output power from the triboelectric nanogenerator; a supercapacitor for storing energy harvested from the triboelectric nanogenerator; a voltage regulator and energy monitoring circuitry for regulating harvested energy from the triboelectric nanogenerator; data integrated circuit to generate a payload message by modulating tree information using an FM modulator; and a unique tree ID for tree identification at a receiver end.

Example 4 is an apparatus according to any examples herein, in particular example 1, wherein the data transmission system comprises: a phase locked loop to generate a dual band transmission signal, wherein the phase locked loop comprises; an integer divider to generate an adjustment signal by dividing the dual band transmission signal with an integer constant; a phase detector to generate an error signal using the reference signal from the crystal oscillator and the adjustment signal; a charge pump to adjust a phase of the error signal; and a dual control voltage controlled oscillator to generate the dual band transmission signal using a payload message from the integrated circuit and a phase adjusted signal from the charge pump; a dual band amplifier that amplifies the dual band transmission signal; and helical and patch antennas to transmit the amplified dual band transmission signal to the one or more base stations.

Example 5 is an apparatus according to any examples herein, in particular example 1, wherein the triboelectric nanogenerator is able to generate enough power to drive the integrated circuit, harvesting interface, and other electronics without requiring an additional power source.

Example 6 is an apparatus according to any examples herein, in particular example 1, wherein the mechanical spring acts as an antenna at a low frequency band for transmitting a payload message of a tree to the one or more base stations.

Example 7 is an apparatus according to any examples herein, in particular example 1, wherein the patch antenna lies outside a tree and works at a different frequency band than the mechanical spring.

Example 8 is an apparatus according to any examples herein, in particular example 1, wherein the integrated circuit use any modulation or error detection technique suited for the application.

Example 9 is an apparatus according to any examples herein, in particular example 1, wherein the sensing system uses a triangulation technique with three or more base stations to determine a precise location of the sensing system.

Example 10 is an apparatus according to any examples herein, in particular example 1, wherein the sensing system is lightweight, making it sensitive to small perturbations, to generate power even with minimal wind speeds.

Example 11 is an apparatus according to any examples herein, in particular example 1, wherein the nail-shaped casing is designed to ease the insertion of the sensing system into a plant or a tree.

Example 12 is an apparatus according to any examples herein, in particular example 1, wherein the sensing system lies outside the body of the tree.

Example 13 is a method of communicating a payload message of a tree using an insertable IoTr based self-powered sensing system, the method comprising: inserting a nail-shaped casing in a tree, wherein the nail-shaped casing houses the sensing system; generating a triboelectric charge using a triboelectric nanogenerator of contact-separation mode, wherein the triboelectric nanogenerator comprises a first triboelectric material coated on a mechanical mass and a second triboelectric material of opposite polarity near the mechanical mass; storing the generated triboelectric charge in a supercapacitor; harvesting regulated DC voltage from the stored triboelectric charge using a harvesting interface; supplying the harvested regulated DC voltage to integrated circuit and a data transmission system; modulating the payload message using integrated circuit into a modulated signal; transmitting the modulated signal using a mechanical spring or a patch antenna to one or more base stations; receiving the modulated signal at one or more base stations; and demodulating the modulated signal to determine a unique tree ID.

Example 14 is a method according to any examples herein, in particular example 13, wherein the mechanical spring acts as a helical antenna at a low frequency band for transmitting the payload message to the one or more base stations.

Example 15 is a method according to any examples herein, in particular example 13, wherein the patch antenna lies outside a tree and works at a different frequency band than the mechanical spring acting as a helical antenna.

Example 16 is a method according to any examples herein, in particular example 13, wherein the integrated circuit use any modulation or error detection technique suited for the application.

Example 17 is a method according to any examples herein, in particular example 13, wherein a triangulation technique is used for the received signal to determine a precise location of the sensing system.

Example 18 is a method according to any examples herein, in particular example 13, wherein the sensing system lies outside the body of the tree.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate example.

What is claimed is:

1. An apparatus comprising:
a triboelectric nanogenerator configured to operate in a contact-separation mode to generate electrical energy, wherein the triboelectric nanogenerator comprises:
a mechanical mass coated with a first triboelectric material on a bottom surface of the mechanical mass;
a second triboelectric material placed adjacent to the mechanical mass, wherein the second triboelectric material is of an opposite polarity than the first triboelectric material; and
a mechanical spring configured to aid the contact-separation mode of the first triboelectric material and the second triboelectric material;
a harvesting interface configured to convert an output of the triboelectric nanogenerator to a DC voltage, wherein the harvesting interface includes a supercapacitor to store harvested electrical energy based on the DC voltage;
an integrated circuit coupled to the triboelectric nanogenerator;
a crystal oscillator coupled to the integrated circuit, the crystal oscillator configured to generate a reference signal for a phase locked loop; and
a data transmission system coupled to the integrated circuit, wherein the data transmission system is configured to transmit a transmission signal to one or more base stations.

2. The apparatus of claim 1, wherein the triboelectric nanogenerator is housed in a nail-shaped casing.

3. The apparatus of claim 1, wherein the mechanical spring is conductive and elastic, wherein the mechanical spring is configured to aid generation of triboelectricity by controlling an extent of vertical back and forth motion of the mechanical mass, and wherein the mechanical spring acts as an antenna and aids in transferring data associated with a moveable object to the one or more base stations.

4. The apparatus of claim 1, wherein the integrated circuit is powered if the harvested electrical energy stored in the supercapacitor is more than a threshold, and wherein the integrated circuit comprises:
a power and charging control circuitry for controlling an output power from the triboelectric nanogenerator, wherein the supercapacitor stores energy harvested from the triboelectric nanogenerator;
a voltage regulator and energy monitoring circuitry for regulating harvested energy from the triboelectric nanogenerator;
data integrated circuit to generate a payload message by modulating information associated with a moveable object with an FM modulator; and
a unique tree ID for identification of the moveable object at a receiver end.

5. The apparatus of claim 1, wherein the data transmission system comprises:
the phase locked loop to generate a dual band transmission signal, wherein the phase locked loop comprises:
an integer divider to generate an adjustment signal by dividing the dual band transmission signal with an integer constant;
a phase detector to generate an error signal using the reference signal from the crystal oscillator and the adjustment signal;
a charge pump to adjust a phase of the error signal; and
a dual control voltage controlled oscillator to generate the dual band transmission signal with a payload message from the integrated circuit and a phase adjusted signal from the charge pump;
a dual band amplifier that amplifies the dual band transmission signal; and
helical and patch antennas to transmit the amplified dual band transmission signal to the one or more base stations.

6. The apparatus of claim 1, wherein the triboelectric nanogenerator is configured to power the integrated circuit and the harvesting interface independent of an additional power source.

7. The apparatus of claim 1, wherein the mechanical spring acts as an antenna at a frequency band configured to transmit a payload message of a moveable object to the one or more base stations.

8. The apparatus of claim 5, wherein the helical and patch antennas are positioned outside a moveable object and works at a different frequency band than the mechanical spring.

9. The apparatus of claim 1, wherein the integrated circuit applies a modulation or error detection technique.

10. The apparatus of claim 1, wherein the one or more base stations apply a triangulation technique to determine a precise location of a sensing system.

11. The apparatus of claim 1, wherein the triboelectric nanogenerator is sensitive to small perturbations to generate power.

12. The apparatus of claim 2, wherein the triboelectric nanogenerator, the harvesting interface, the integrated circuit, the crystal oscillator, and the data transmission system are configured to insert into a moveable object.

13. The apparatus of claim 10, wherein the sensing system lies outside a body of a moveable object.

14. A method of communicating a payload message of a moveable object using a sensing system, the method comprising:
inserting a nail-shaped casing in the moveable object, wherein the nail-shaped casing houses the sensing system;
generating a triboelectric charge with a triboelectric nanogenerator in a contact-separation mode, wherein the triboelectric nanogenerator comprises a first triboelectric material coated on a mechanical mass and a second triboelectric material of opposite polarity adjacent to the mechanical mass;
storing the triboelectric charge in a supercapacitor;
harvesting regulated DC voltage from the triboelectric charge that is stored;
supplying the harvested regulated DC voltage to integrated circuit and a data transmission system;
modulating the payload message with the integrated circuit into a modulated signal; and
transmitting the modulated signal with a mechanical spring or a patch antenna to one or more base stations, wherein the modulated signal is received at one or more base stations, and wherein the one or more base stations demodulate the modulated signal to determine a unique ID.

15. The method of claim 14, wherein the mechanical spring acts as a helical antenna at a frequency band for transmitting the payload message to the one or more base stations.

16. The method of claim 14, wherein the patch antenna lies outside the movable object and works at a different frequency band than the mechanical spring acting as a helical antenna.

17. The method of claim 14, wherein the integrated circuit applies a modulation or error detection technique.

18. The method of claim 14, wherein a triangulation technique is applied for the received modulated signal to determine a precise location of the sensing system.

19. The method of claim 14, wherein the sensing system lies outside a body of the moveable object.
